(19) United States
(12) Patent Application Publication
(10) Pub. No.: US 2015/0021574 A1
(43) Pub. Date: Jan. 22, 2015

(54) MATERIAL FOR AN ORGANIC ELECTROLUMINESCENCE DEVICE AND ORGANIC ELECTROLUMINESCENCE DEVICE USING THE SAME

(71) Applicant: SAMSUNG DISPLAY CO., LTD., Yongin-City (KR)

(72) Inventor: Hiroaki ITOI, Yokohama (JP)

(21) Appl. No.: 14/329,217

(22) Filed: Jul. 11, 2014

(30) Foreign Application Priority Data
Jul. 18, 2013 (JP) 2013-149507

(51) Int. Cl. H01L 51/00

(52) U.S. Cl. CPC H01L 51/0054; H01L 51/0072; H01L 51/0058; H01L 51/5056
USPC 257/40; 548/427; 548/420

(57) ABSTRACT

A material for an organic electroluminescence device and an organic electroluminescence device using the same, the material being represented by the following Formula 1:

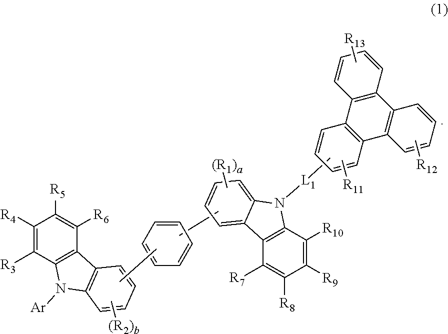

### CROSS-REFERENCE TO RELATED APPLICATION

Japanese Patent Application No. 2013-149507, filed on Jul. 18, 2013, in the Japanese Patent Office, and entitled: “Material For Organic Electroluminescence Device and Organic Electraluminescence Device Using the Same,” is incorporated by reference herein in its entirety.

### BACKGROUND

1. Field

Embodiments relate to a material for an organic electroluminescence device and an organic electroluminescence device using the same.

2. Description of the Related Art

In recent years, organic electroluminescence (EL) displays that are one type of image displays have been actively developed. Unlike a liquid crystal display and the like, the organic EL display is a self-luminescent display in which holes and electrons (injected from a positive electrode and a negative electrode) recombine in an emission layer to thus emit light (from a light-emitting material including an organic compound of the emission layer), thereby performing display.

An example of an organic electroluminescence device (hereinafter referred to as an organic EL device) may include an organic EL device that includes a positive electrode, a hole transport layer on the positive electrode, an emission layer on the hole transport layer, an electron transport layer on the emission layer, and a negative electrode on the electron transport layer. Holes injected from the positive electrode may be injected into the emission layer via the hole transport layer. Electrons may be injected from the negative electrode, and then injected into the emission layer via the electron transport layer. The holes and the electrons injected into the emission layer may be recombined to generate excitons within the emission layer. The organic EL device may emit light by using lights generated by the radiation and deactivation of the excitons.

### SUMMARY

Embodiments are directed to a material for an organic electroluminescence device and an organic electroluminescence device using the same.

The embodiments may be realized by providing a material for an electroluminescence device, the material being represented b the following Formula 1:

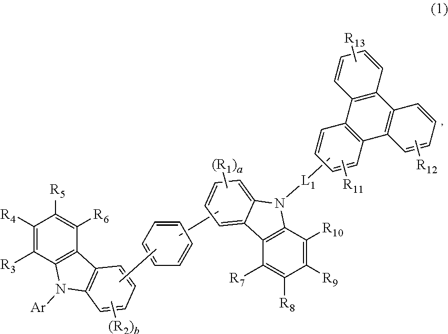

wherein Ar is an aryl group having 6 to 30 carbon atoms, a heteroaryl group having 5 to 30 carbon atoms, or an alkyl group having 1 to 15 carbon atoms, R₁ to R₁₃ are each independently an aryl group having 6 to 30 carbon atoms, a heteroaryl group having 5 to 30 carbon atoms, an alkyl group having 1 to 15 carbon atoms, a halogen atom, a hydrogen, or a deuterium, L₁ is a single bond or a divalent connecting group having 4 or more carbon atoms, and a and b are each independently an integer of 0 to 3.

The embodiments may be realized by providing a material for an electroluminescence device, the material being represented by the following Formula 2:

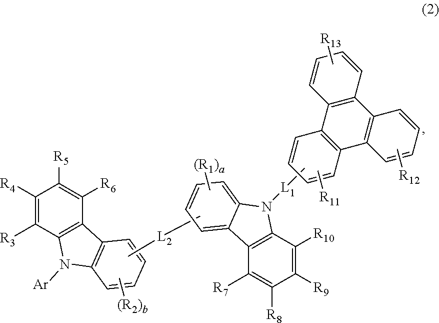

wherein Ar is an aryl group having 6 to 30 carbon to s, a heteroaryl group having 5 to 30 carbon atoms, or an alkyl group having 1 to 15 carbon atoms. R₁ to R_{1 3} are each independently an aryl group having 6 to 30 carbon atoms, a heteroaryl group having 5 to 30 carbon atoms, an alkyl group having 1 to 15 carbon atoms, a halogen atom, a hydrogen, or a deuterium, L₁ and L₂ are each independently a single bond or a divalent connecting group having 4 or more carbon atoms, and a and b are each independently an integer of 0 to 3.

The embodiments may be realized by providing a material for an electroluminescence device, the material being represented by the following Formula 3:

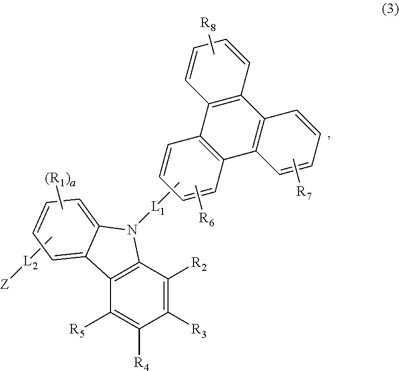

wherein R₁ to R₈ are each independently an aryl group having 6 to 30 carbon atoms, a heteroaryl group having 5 to 30 carbon atoms, an alkyl group having 1 to 15 carbon atoms, a halogen atom or a deuterium, L₁ is a single bond or a divalent connecting group having 4 or more carbon atoms, L₂ is a divalent connecting group having 4 or more carbon atoms, Z is an aryl group having 6 to 30 carbon atoms or a heteroaryl group having 5 to 30 carbon atoms, and a is an integer of 0 to 3.

The embodiments may be realized by providing an electroluminescence device including an emission layer; and a positive electrode, wherein the material for an electroluminescence device according to an embodiment is in the emission layer or in another layer between the emission layer and the positive electrode.

### BRIEF DESCRIPTION OF THE DRAWING

Features will be apparent to those of skill in the art by describing in detail exemplary embodiments with reference to the attached drawing in which:

FIG. 1 illustrates the a of an organic EL device according to an embodiment.

### DETAILED DESCRIPTION

Example embodiments will now be described more fully hereinafter with reference to the accompanying drawing; however they may be embodied in different forms and should not be construed as limited to the embodiments set forth herein. Rather, these embodiments are provided so that this disclosure will be thorough and complete, and will full convey exemplary implementations to those skilled in the art.

In the drawing figure, the dimensions of layers and regions may be exaggerated for clarity of illustration. Like reference numerals refer to like elements throughout.

An organic EL device having high efficiency and long life may be realized by using a material for an organic EL device including a triphenylene unit or moiety and a carbazole moiety, e.g., including the triphenylene moiety in or on a carbazole containing skeleton.

The material for an organic EL device according to an embodiment may be a carbazole derivative, e.g., may include a carbazole moiety, and may include a triphenylene moiety or unit, e.g., in or on a carbazole-containing skeleton, as represented by the following Formula 3.

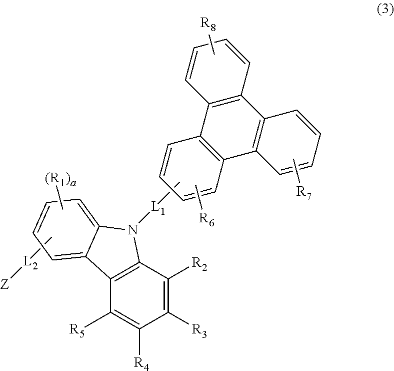

In Formula 3, R₁ to R₈ may each independently be an aryl group having 6 to 30 carbon atoms, a heteroaryl group having 5 to 30 carbon atoms, an alkyl group having 1 to 15 carbon atoms, a halogen atom, a hydrogen, or a deuterium. L₁ may be a single bond or a divalent connecting group having 4 or more carbon atoms. L₂ may be a divalent connecting group having 4 or more carbon atoms. Z may be an aryl group having 6 to 30 carbon atoms or a heteroaryl group having 5 to 30 carbon atoms, a may be an integer of 0 to 3.

By introducing a triphenylene unit in or on a carbazole-containing skeleton in the material for an organic EL device according to an embodiment, hole transporting properties and electron resistance may be improved, and a hole transport layer having high efficiency and long life may be formed in an organic EL device.

In an implementation, in Formula 3, adjacent ones of R₁ to R₈ may be combined, fused, or may form a saturated or unsaturated ring. In an implementation, the combination or the forming of the ring may not be made between R₁ and R₅, or between R₆, R₇, and R₈.

In an implementation, the material for an organic EL device may include two carbazole moieties, e.g., may be represented by the following Formula 2, in which a triphenylene moiety is introduced in or on one carbazole moiety.

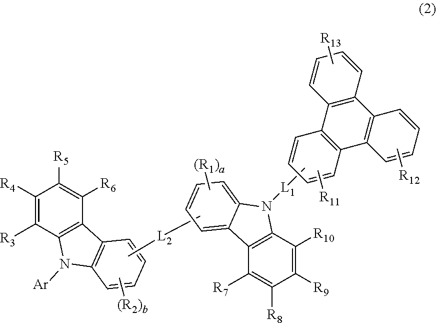

In Formula 2, Ar may be an aryl group having 6 to 30 carbon atoms, a heteroaryl group having 5 to 30 carbon atoms, or an alkyl group having 1 to 15 carbon atoms. R₁ to R₁₃ may each independently be an aryl group having 6 to 30 carbon atoms, a heteroaryl group having 5 to 30 carbon atoms, an alkyl group having 1 to 15 carbon atoms, a halogen atom, a hydrogen, or a deuterium. L₁ and L₂ may each independently be a single bond or a divalent connecting group having 4 or more carbon atoms, a and b may each independently be an integer of 0 to 3.

The material for an organic EL device according to an embodiment may include two carbazole moieties (exhibiting hole transport properties) combined or bound through the, e.g., divalent connecting group, L₂. One carbazole moiety may be a carbazole derivative introducing or bound to a triphenylene moiety having high electron resistance, and an improvement of hole transport properties and electron resistance may be expected.

In an implementation, in Formula 2, adjacent ones of R₁ to R₁₃ may be combined, fused, or may form a saturated or unsaturated ring. In an implementation, the combination or the forming of an aromatic ring may not be made between R₁ and R₇, between R₂ and R₆, or between R₁₁, R₁₂, and R ₁₃.

In an implementation, the material for an organic EL device may include two carbazole moieties, e.g., may be represented by the following Formula I, e.g., in which a triphenylene moiety is introduced in or bound (directly or indirectly to) one carbazole moiety.

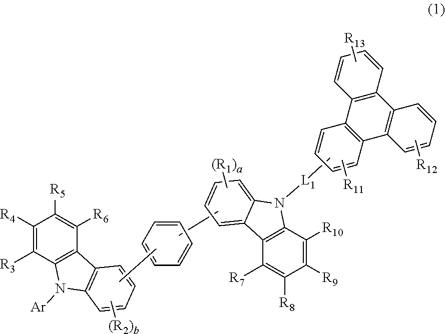

In Formula 1, Ar may be an aryl group having 6 to 30 carbon atoms, a heteroaryl group having 5 to 30 carbon atoms, or an alkyl group having 1 to 15 carbon atoms. R₁ to R₁₃ may each independently be an aryl group having 6 to 30 carbon atoms, a heteroaryl group having 5 to 30 carbon atoms, an alkyl group having 1 to 15 carbon atoms, a halogen, atom, a hydrogen, or a deuterium. L₁ may be a single bond or a divalent connecting group having 4 or more carbon atoms. a and b may each independently be an integer of 0 to 3.

The material for an organic EL device according, to an embodiment may include two carbazole moieties bound through a phenylene group, a degree of conjugation of the whole compound may be appropriately high, and an improvement of the hole transport properties may be expected. In addition, the material of an organic EL device according to an embodiment may include a carbazole moiety and a triphenylene moiety (having high electron resistance) in or on one carbazole moiety, and an improvement of the electron resistance may be expected.

In an implementation, in Formula 1, adjacent ones of R₁ to R₁₃ may be combined or may form a saturated or unsaturated ring. In an implementation, the combination or the forming of an aromatic ring may not be made between R₁ and R₇, between R₂ and R₆, or between R₁₁, R₁₂, and R₁₃.

The material for an organic EL device according to an embodiment may include one of the following Compounds 1 to 24.

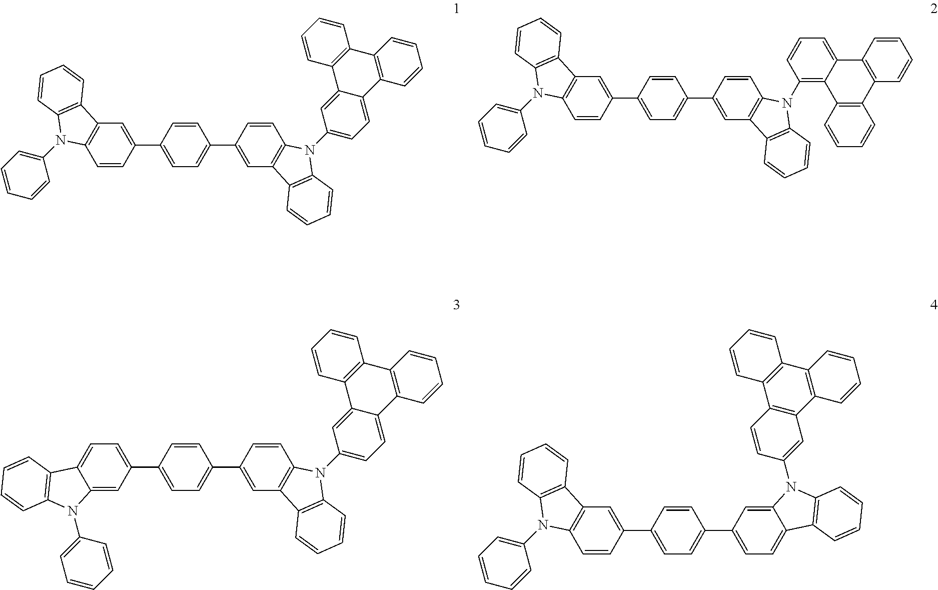 [SMILES: c1ccc(-n2c3ccccc3c3cc(-c4ccc(-c5ccc6c(c5)c5ccccc5n6-c5ccc6c7ccccc7c7ccccc7c6c5)cc4)ccc32)cc1 ; c1ccc(-n2c3ccccc3c3cc(-c4ccc(-c5ccc6c(c5)c5ccccc5n6-c5cccc6c7ccccc7c7ccccc7c56)cc4)ccc32)cc1 ; c1ccc(-n2c3ccccc3c3ccc(-c4ccc(-c5ccc6c(c5)c5ccccc5n6-c5ccc6c7ccccc7c7ccccc7c6c5)cc4)cc32)cc1 ; c1ccc(-n2c3ccccc3c3cc(-c4ccc(-c5ccc6c7ccccc7n(-c7ccc8c9ccccc9c9ccccc9c8c7)c6c5)cc4)ccc32)cc1]

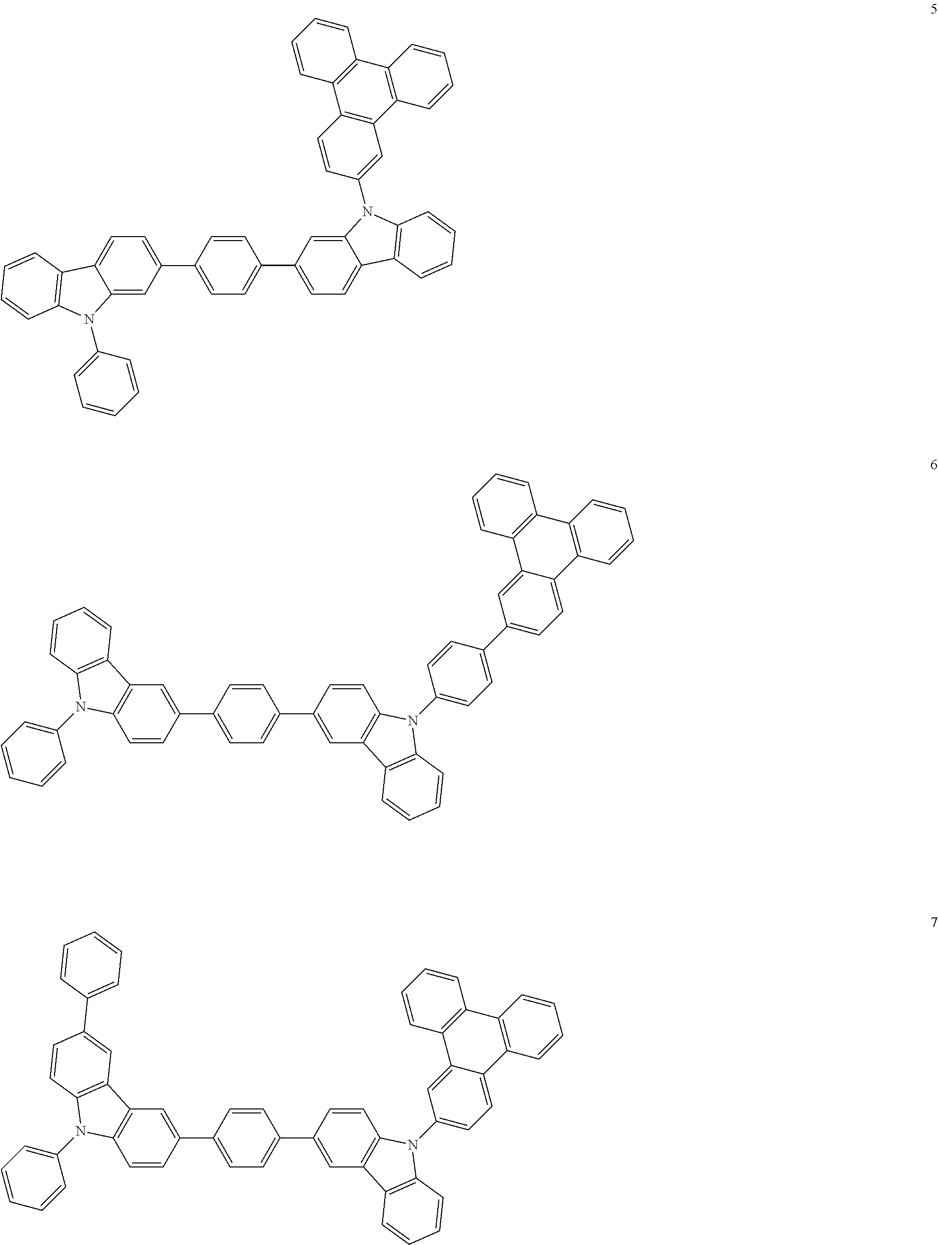 [SMILES: c1ccc(-n2c3ccccc3c3ccc(-c4ccc(-c5ccc6c7ccccc7n(-c7ccc8c9ccccc9c9ccccc9c8c7)c6c5)cc4)cc32)cc1 ; c1ccc(-n2c3ccccc3c3cc(-c4ccc(-c5ccc6c(c5)c5ccccc5n6-c5ccc(-c6ccc7c8ccccc8c8ccccc8c7c6)cc5)cc4)ccc32)cc1 ; c1ccc(-c2ccc3c(c2)c2cc(-c4ccc(-c5ccc6c(c5)c5ccccc5n6-c5ccc6c7ccccc7c7ccccc7c6c5)cc4)ccc2n3-c2ccccc2)cc1]

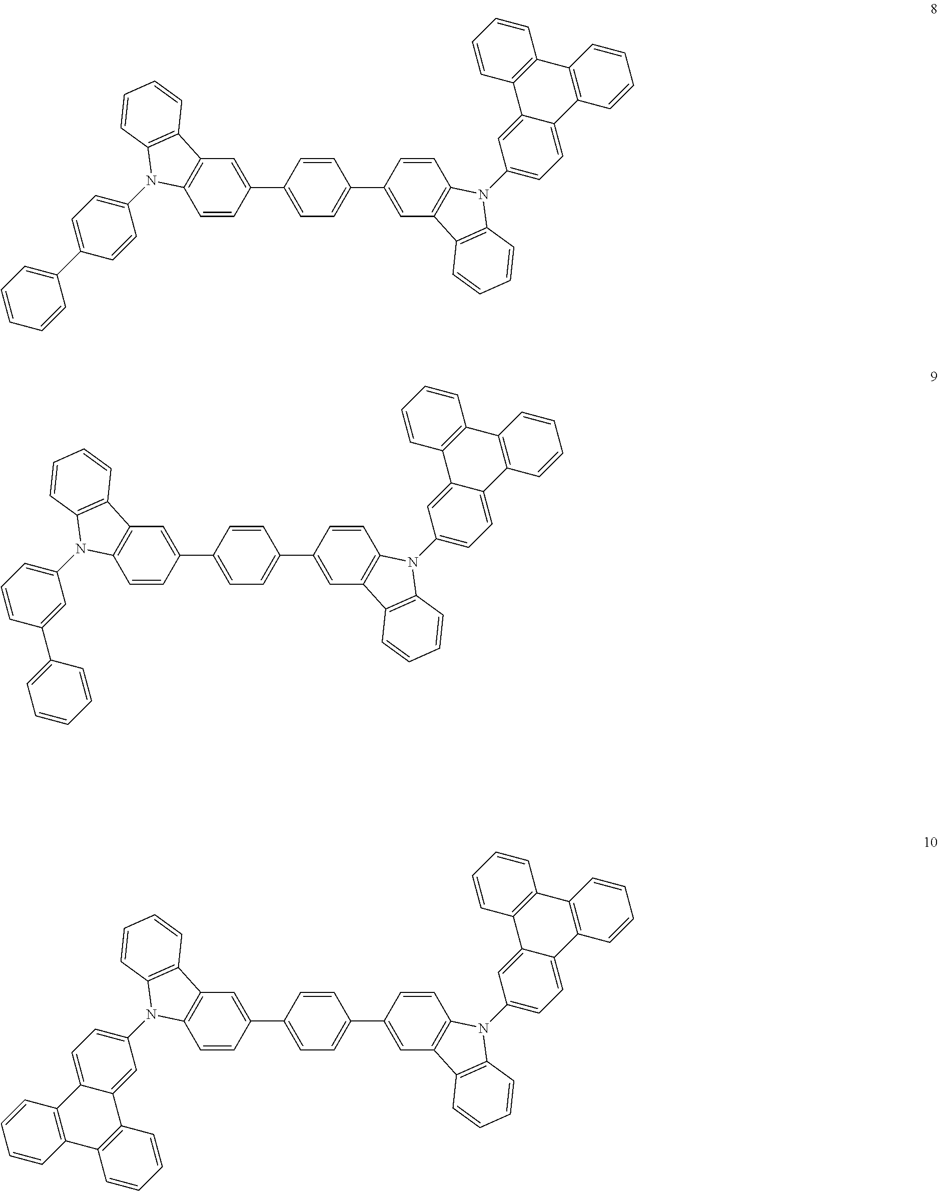 [SMILES: c1ccc(-c2ccc(-n3c4ccccc4c4cc(-c5ccc(-c6ccc7c(c6)c6ccccc6n7-c6ccc7c8ccccc8c8ccccc8c7c6)cc5)ccc43)cc2)cc1 ; c1ccc(-c2cccc(-n3c4ccccc4c4cc(-c5ccc(-c6ccc7c(c6)c6ccccc6n7-c6ccc7c8ccccc8c8ccccc8c7c6)cc5)ccc43)c2)cc1 ; c1ccc2c(c1)c1ccccc1c1cc(-n3c4ccccc4c4cc(-c5ccc(-c6ccc7c(c6)c6ccccc6n7-c6ccc7c8ccccc8c8ccccc8c7c6)cc5)ccc43)ccc21]

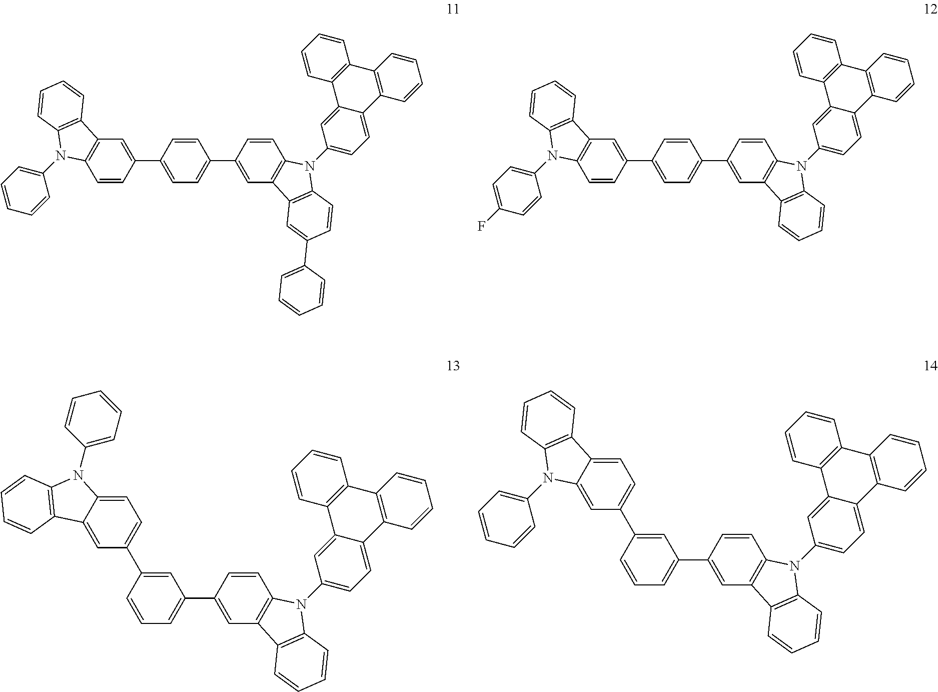 [SMILES: c1ccc(-c2ccc3c(c2)c2cc(-c4ccc(-c5ccc6c(c5)c5ccccc5n6-c5ccccc5)cc4)ccc2n3-c2ccc3c4ccccc4c4ccccc4c3c2)cc1 ; Fc1ccc(-n2c3ccccc3c3cc(-c4ccc(-c5ccc6c(c5)c5ccccc5n6-c5ccc6c7ccccc7c7ccccc7c6c5)cc4)ccc32)cc1 ; c1ccc(-n2c3ccccc3c3cc(-c4cccc(-c5ccc6c(c5)c5ccccc5n6-c5ccc6c7ccccc7c7ccccc7c6c5)c4)ccc32)cc1 ; c1ccc(-n2c3ccccc3c3ccc(-c4cccc(-c5ccc6c(c5)c5ccccc5n6-c5ccc6c7ccccc7c7ccccc7c6c5)c4)cc32)cc1]

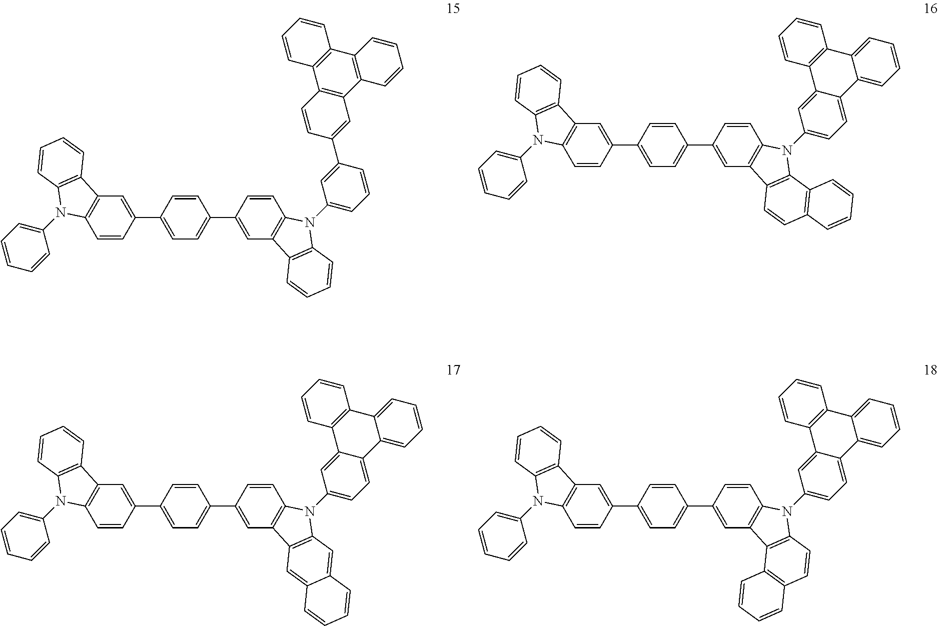 [SMILES: c1ccc(-n2c3ccccc3c3cc(-c4ccc(-c5ccc6c(c5)c5ccccc5n6-c5cccc(-c6ccc7c8ccccc8c8ccccc8c7c6)c5)cc4)ccc32)cc1 ; c1ccc(-n2c3ccccc3c3cc(-c4ccc(-c5ccc6c(c5)c5ccc7ccccc7c5n6-c5ccc6c7ccccc7c7ccccc7c6c5)cc4)ccc32)cc1 ; c1ccc(-n2c3ccccc3c3cc(-c4ccc(-c5ccc6c(c5)c5cc7ccccc7cc5n6-c5ccc6c7ccccc7c7ccccc7c6c5)cc4)ccc32)cc1 ; c1ccc(-n2c3ccccc3c3cc(-c4ccc(-c5ccc6c(c5)c5c7ccccc7ccc5n6-c5ccc6c7ccccc7c7ccccc7c6c5)cc4)ccc32)cc1]

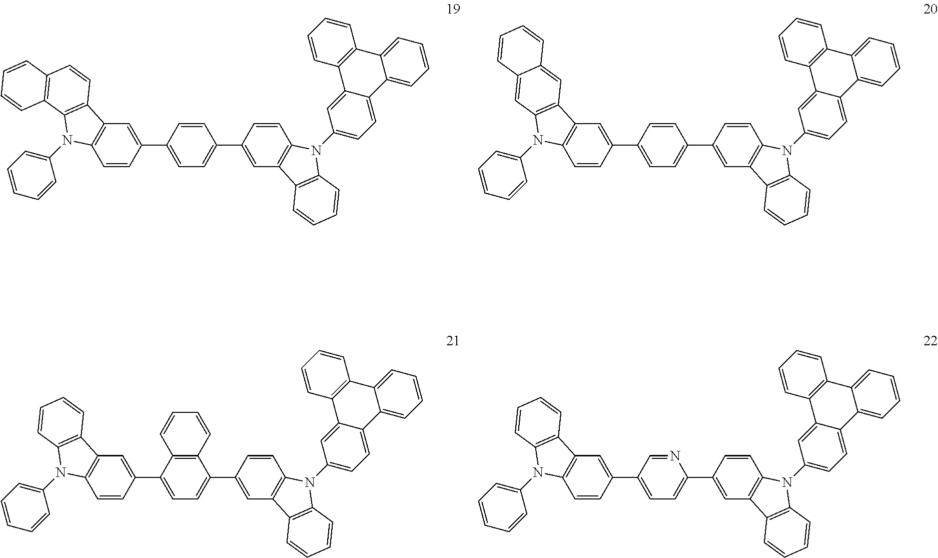 [SMILES: c1ccc(-n2c3ccc(-c4ccc(-c5ccc6c(c5)c5ccccc5n6-c5ccc6c7ccccc7c7ccccc7c6c5)cc4)cc3c3ccc4ccccc4c32)cc1 ; c1ccc(-n2c3ccc(-c4ccc(-c5ccc6c(c5)c5ccccc5n6-c5ccc6c7ccccc7c7ccccc7c6c5)cc4)cc3c3cc4ccccc4cc32)cc1 ; c1ccc(-n2c3ccccc3c3cc(-c4ccc(-c5ccc6c(c5)c5ccccc5n6-c5ccc6c7ccccc7c7ccccc7c6c5)c5ccccc45)ccc32)cc1 ; c1ccc(-n2c3ccccc3c3cc(-c4ccc(-c5ccc6c(c5)c5ccccc5n6-c5ccc6c7ccccc7c7ccccc7c6c5)nc4)ccc32)cc1]

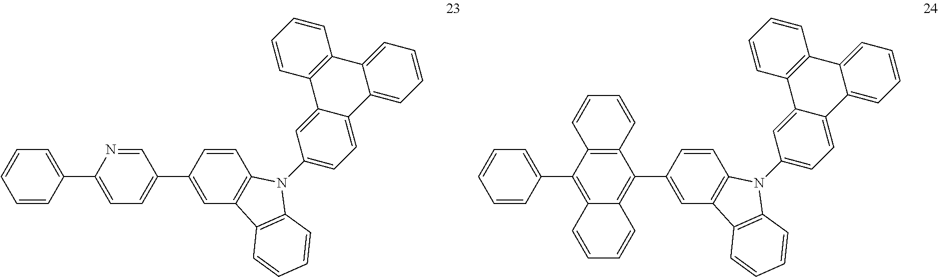 [SMILES: c1ccc(-c2ccc(-c3ccc4c(c3)c3ccccc3n4-c3ccc4c5ccccc5c5ccccc5c4c3)cn2)cc1 ; c1ccc(-c2c3ccccc3c(-c3ccc4c(c3)c3ccccc3n4-c3ccc4c5ccccc5c5ccccc5c4c3)c3ccccc23)cc1]

The material for an organic EL device according to an embodiment may be suitably used or included in an emission layer of an organic EL device. In an implementation, the material for an organic EL device may be used or included in a layer among stacked layers that are between the emission layer and a positive electrode of an organic EL device. For example, the hole transporting properties and the electron resistance of a layer including the material for an organic EL device according to an embodiment may be improved, and the high efficiency and the long life of the organic EL device may be realized. In addition, the material for an organic EL device according to an embodiment may be suitably used in an emission layer or a layer between the emission layer and a positive electrode in an organic EL device having a blue emission region.

Organic EL Device

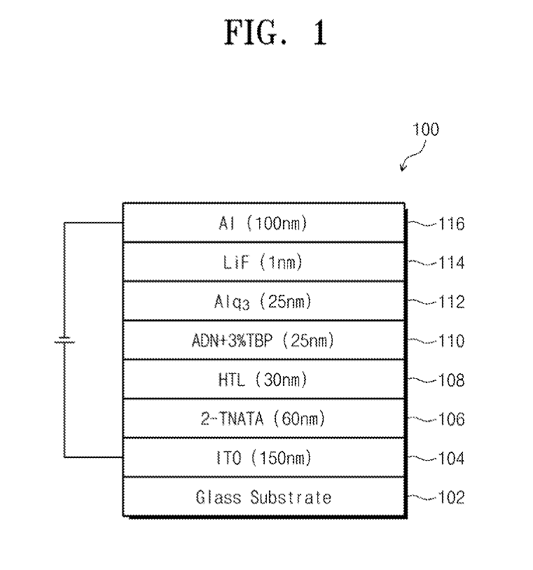

An organic EL device using the material for an organic EL device according to an embodiment will be explained. FIG. 1 illustrates a schematic diagram of the configuration of an organic EL device 100 according to an embodiment. The organic EL device 100 may include, e.g., a substrate 102, a positive electrode 104, a hole injection layer 106, a hole transport layer 108, an emission layer 110, an electron transport layer 112, an electron injection layer 114, and a negative electrode 116. In an implementation, the material for an organic EL device according to an embodiment may be used or included in the emission layer. In an implementation, the material for an organic EL device according to an embodiment may be used or included in one of the layers between the emission layer and the positive electrode.

Here, an embodiment using the material for an organic EL device according to an embodiment in the hole transport layer 108 will be explained. The substrate 102 may be a transparent glass substrate, a semiconductor substrate formed by using silicon, or the like, or a flexible substrate. The positive electrode 104 may be on the substrate 102, and may be formed by using indium tin oxide (ITO), indium zinc oxide (IZO), or the like. The hole injection layer 106 may be on the positive electrode 104 and may include, e.g., 4,4′,4″-tris(N-1-naphthyl)-N-phenylamino)-triphenylamine (1-TNATA), 4,4′,4″-tris(N-2-naphthyl)-N-phenylamino)-triphenylamine (2-TNATA), or 4,4-bis[N,N-di(3-tolyl)amino]-3,3-dimethylbiphenyl (HMTPD), or the like. The hole transport layer 108 may be on the hole injection layer 106, and may be formed using the material for an organic EL device according to an embodiment. The emission layer 110 may be on the hole transport layer 108, and may be formed by, e.g., doping tetra-t-butylperylene (TBP), or the like in a host material including e,g., 9,10-di(2-naphthyl)anthracene (ADN). The electron transport layer 112 may be on the emission layer 110, and may be formed by using., e.g., tris(8-hydroxyquinolinato)aluminum (Alq₃), or the like. The electron injection layer 114 may be on the electron transport layer 112, and may be formed by using a material including, e.g., lithium fluoride (LiF). The negative electrode 116 may be on the electron injection layer 114, and may be formed using a metal such as Al or a transparent material such as ITO, IZO, or the like. The above-described layers may be formed by selecting an appropriate layer forming method such as vacuum deposition, sputtering, various coatings, or the like.

In the organic EL device 100 according to the present embodiment, a hole transport layer having high efficiency and long life may be formed by using, the material for an organic EL device described above. In addition, the material for an organic EL device according to an embodiment may be applied in an organic EL apparatus of an active matrix using thin film transistors (TFT).

In addition, in the organic EL device 100 according to the present embodiment, high efficiency and long life may be realized by using the material for an organic EL device described above in an emission layer or in a layer between the emission layer and a positive electrode.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

Preparation Method

A material for an organic EL device according to an embodiment may be synthesized, e.g., by the following method in Reaction Scheme 1.

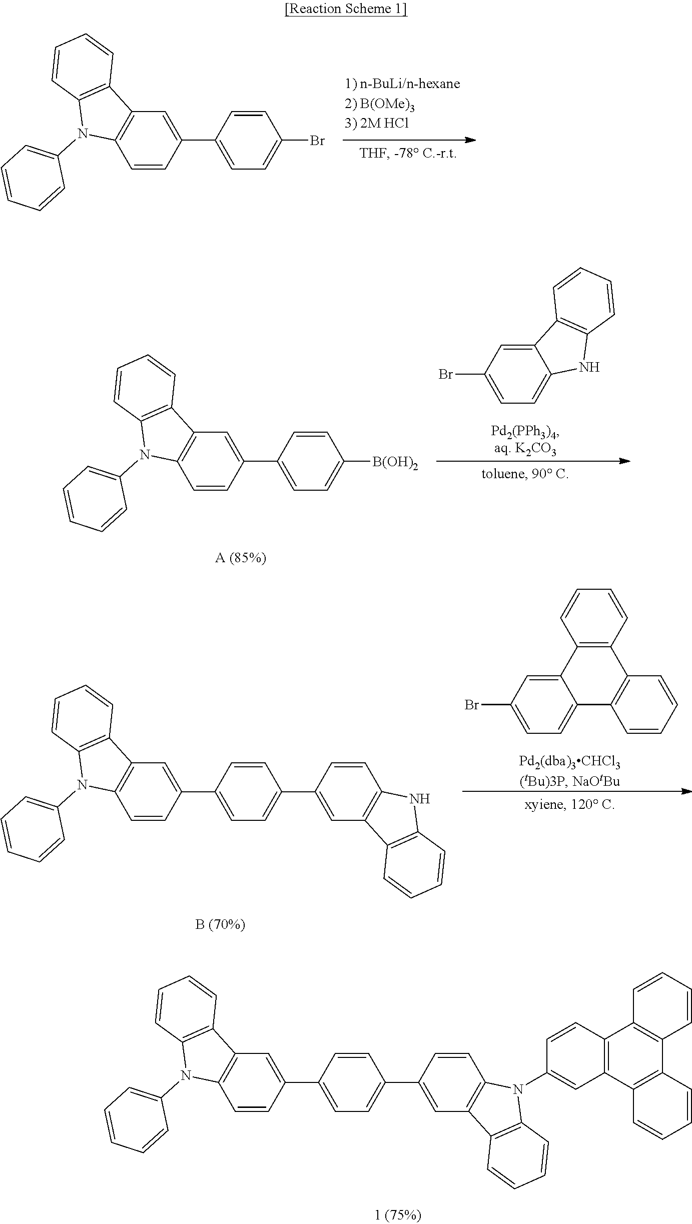 [SMILES: Brc1ccc(-c2ccc3c(c2)c2ccccc2n3-c2ccccc2)cc1 ; OB(O)c1ccc(-c2ccc3c(c2)c2ccccc2n3-c2ccccc2)cc1 ; Brc1ccc2[nH]c3ccccc3c2c1 ; c1ccc(-n2c3ccccc3c3cc(-c4ccc(-c5ccc6[nH]c7ccccc7c6c5)cc4)ccc32)cc1 ; Brc1ccc2c3ccccc3c3ccccc3c2c1 ; c1ccc(-n2c3ccccc3c3cc(-c4ccc(-c5ccc6c(c5)c5ccccc5n6-c5ccc6c7ccccc7c7ccccc7c6c5)cc4)ccc32)cc1]

(Synthesis of Compound A)

Under an argon atmosphere, 20.0 g of 3-(4-bromophenyl)-9-phenyl-9H-carbazole was added in a 1 L, four-necked flask, and stirred in 350 mL of a tetrahydrofuran (THF) solvent at −78° C. for 5 minutes. Then, 36.7 mL of 1.64 M n-butyl lithium (in n-hexane) was added thereto, followed by stirring at −78° C. for 1 hour, 11.2 mL of trimethoxyborane was added thereto, followed by stirring at ambient (e.g., room) temperature for 2 hours. After that, 200 ml of 2M aqueous hydrochloric acid solution was added, followed by stirring at ambient temperature for 3 hours. An organic layer was separated, and solvents were distillated. Recrystallization was performed in a solvent system of ethyl acetate and hexane to obtain 15.69 g of Compound A as a white solid (yield 85%).

(Synthesis of Compound B)

Under an argon atmosphere, 14.0 g of Compound A, 10.4 g of 3-bromocarbazole, 312 g of tetrakis(triphenylphosphine) palladium (Pd(PPh₃)₄), 10.7 g of potassium carbonate (K₂CO₃), 80 mL of water, 30 mL of ethanol, and 400 ml of toluene were added in a 1 L, four-necked flask, and stirred at 90° C. for 4 hours. After cooling in the air, an organic layer was separated, and solvents were distilled. Then, recrystallization was performed using toluene to obtain 13.1 g of Compound B as a white solid (yield 70%).

(Synthesis of Compound 1)

Under an argon atmosphere, 9.70 g of Compound B, 6.76 g of 2-bromotriphenylene, 1.45 g of tris(dibenzylideneacetone)dipalladium(O) (Pd₂(dba)₃), 510 mg of tri-tert-butyl(phosphine) ((t-Bu)₃P), and 5.77 g of sodium tert-butoxide were added in a 500 mL three-necked flask and heated while stirring in 50 mL of a xylene solvent at 120° C. for 12 hours. After cooling in the air, water was added thereto to separate an organic layer, and solvents were distilled. The crude product thus obtained was separated by silica gel column chromatography (using a mixture solvent of dichloromethane and hexane), and recrystallization was performed using a mixed solvent of toluene and hexane to obtain 10.7 g of Compound 1 as a white solid (yield 75%).

(Identification of Compounds)

The identification of compounds was conducted by ¹H-NMR and FAB-MS. In the ¹H-NMR measurement, CDCl₃ was used as a solvent.

(Identification of Compound A)

The chemical shift values of Compound A measured by the ¹H-NMR was 8.47(d,1H), 8.40(d,2H), 8,23(d,1H), 7.89(d,1H), 7.75-7.79(m,1H), 7.59-7.64(m,4H), 7.42-7.52(m,4H), 7.25-7.36(m,1 H), 1.58(s,2H).

(Identification of Compound B)

The molecular weight of Compound B measured by FAB-MS was 484.

(Identification of Compound 1)

The chemical shift values of Compound 1 measured by the¹H-NMR was 8.86-8.88(m,2H), 8.69-8.72(m3H), 8.57(d,1H), 8.45(q,2H), 8.20-8.30(m,2H), 7.82-7.88(m,5H), 7.53-7.76(m,12H), 7.28-7.49(m,7H). In addition, the molecular weight of Compound 1 measured by FAB-MS was 710.

According to the above-described method. Compound 1 was obtained and, with slight modifications, Compounds 21 and 24 (below) were obtained.

As Comparative examples, Comparative Compound 1 and Comparative Compound 2 (below) were prepared.

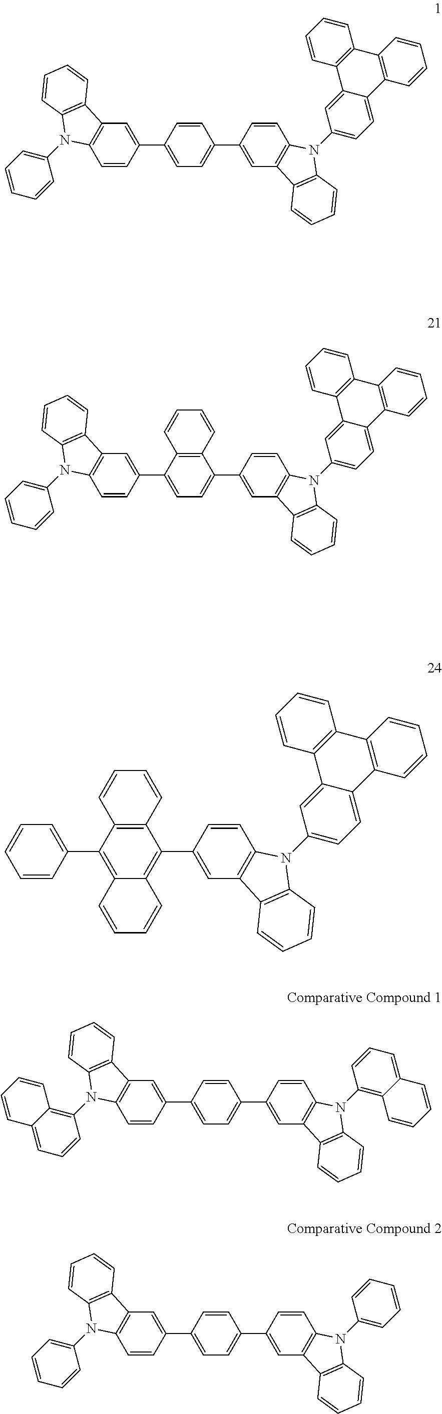 [SMILES: c1ccc(-n2c3ccccc3c3cc(-c4ccc(-c5ccc6c(c5)c5ccccc5n6-c5ccc6c7ccccc7c7ccccc7c6c5)cc4)ccc32)cc1 ; c1ccc(-n2c3ccccc3c3cc(-c4ccc(-c5ccc6c(c5)c5ccccc5n6-c5ccc6c7ccccc7c7ccccc7c6c5)c5ccccc45)ccc32)cc1 ; c1ccc(-c2c3ccccc3c(-c3ccc4c(c3)c3ccccc3n4-c3ccc4c5ccccc5c5ccccc5c4c3)c3ccccc23)cc1 ; c1ccc2c(-n3c4ccccc4c4cc(-c5ccc(-c6ccc7c(c6)c6ccccc6n7-c6cccc7ccccc67)cc5)ccc43)cccc2c1 ; c1ccc(-n2c3ccccc3c3cc(-c4ccc(-c5ccc6c(c5)c5ccccc5n6-c5ccccc5)cc4)ccc32)cc1]

Organic EL devices were manufactured by using the above Compound 1, Compound 21, Compound 24, Comparative Compound 1, and Comparative Compound 2 as hole transport materials. In these experiments, the substrate 102 was formed by using a transparent glass substrate, the positive electrode 104 was formed using ITO to a thickness of about 150 nm, the hole injection layer 106 having a thickness of about 60 urn was formed by using 2-TNATA, the hole transport layer 108 was formed to a thickness of about 30 nm, the emission layer 110 was formed by doping about 3% of TBP in ADN to a thickness of about 25 nm, the electron transport layer 112 was formed using Alq₃ to a thickness of about 25 nm, the electron injection layer 114 was formed using LiF to a thickness of about 1 nm, and the negative electrode 116 was formed using Al to a thickness of about 100 nm.

With respect to the organic EL devices thus manufactured, the voltage, the current efficiency and the half life were evaluated. The current efficiency is the value at 10 mA/cm², and the half life is the time necessary for decreasing the luminance to half from the initial luminance of 1,000 cd/m². The results are illustrated in the following Table 1.

TABLE 1

| | | Current | Half |
|---|---|---|---|
| | Voltage (V) | efficiency (cd/A) | life (h) |
| Compound 1 | 4.7 | 9.5 | 4,300 |
| Compound 21 | 4.9 | 8.9 | 2,800 |
| Compound 24 | 5.1 | 7.1 | 1,900 |
| Comparative | 7.7 | 5.8 | 1,500 |
| Compound 1 | | | |
| Comparative | 7.8 | 5.8 | 1,200 |
| Compound 2 | | | |

As may be seen in Table 1, an organic EL device including Comparative Compound 1 had longer life than that including Comparative Compound 2. In addition, organic EL devices including Compound 1, Compound 21, and Compound 24 were driven at lower voltage, when compared to those including Comparative Compound 1 and Comparative Compound 2. With respect to the current efficiency and the half life, organic EL devices including Compound 1, Compound 21, and Compound 24 had higher current efficiency and longer half life, when compared to those including Comparative Compound 1 and Comparative Compound 2. The organic EL device including Comparative Compound 1 had longer life than that including Comparative Compound 2 because Comparative Compound 1 included a condensed ring, e.g., naphthalene and had higher electron resistance. The hole transport properties and the electron resistance were considered to be improved for Compound 1, Compound 21, and Compound 24, by including a triphenylene moiety in or on a carbazole-containing skeleton. For example, two carbazole moieties (exhibiting hole transporting properties) were included in Compound 1 and Compound 21, and organic EL devices using Compound 1 and Compound 21 (as hole transporting materials) realized good current efficiency and long life.

By way of summation and review, in application of the organic EL device to a display apparatus, high efficiency and long life of the organic EL device should be considered, and normalization, stabilization, and durability of a hole transport layer have been considered to realize the high efficiency and long life of the organic EL device.

As a hole transport material used in a hole transport layer, various compounds, e.g., an anthracene derivative, an aromatic amine compound, or the like, may be used. A carbazole derivative substituted with a condensed ring has been considered as a material for attaining the long life of a device, and as the condensed ring, a triphenylene substituted carbazole derivative has been considered. However, the aromatic amine compound may have low electron resistance, and an organic EL device using the material may not have sufficient emission life. As noted above, an organic EL device may have high efficiency, may be driven by a to voltage, and may have long emission life. For example, the emission efficiency of an organic EL device in a blue emission region may be lower when compared to a red emission region and a green emission region, thus, the emission efficiency may be improved.

The embodiments may provide a material of an organic EL device having high efficiency and long life.

The material for an organic EL device according to an embodiment may have improved hole transporting properties and electron resistance by introducing a triphenylene unit in a carbazole skeleton, and to hole transport layer having high efficiency and long life may be formed in an organic EL device.

The organic EL device according to an embodiment may have improved hole transporting properties and electron resistance by including a material for an organic EL device introducing a triphenylene unit in a carbazole skeleton in an emission layer, and high efficiency and long life may realized in the organic EL device.

The organic EL device according to an embodiment may have improved hole transporting properties and electron resistance by including a material for art organic EL device introducing a triphenylene unit in a carbazole skeleton in to layer between an emission layer and a positive electrode, and high efficiency and long life may be realized in the organic EL device.

The embodiments may provide a hole transport material for an organic electroluminescence device having high efficiency and long life.

In the material for an organic EL device according to an embodiment, a triphenylene moiety may be included in or on a carbazole-containing skeleton, and the hole transporting properties and the electron resistance were improved, and a hole transport layer having high efficiency and long, life may be formed in an organic EL device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed:

1. A material for an electroluminescence device, the material being represented by the following Formula 1: 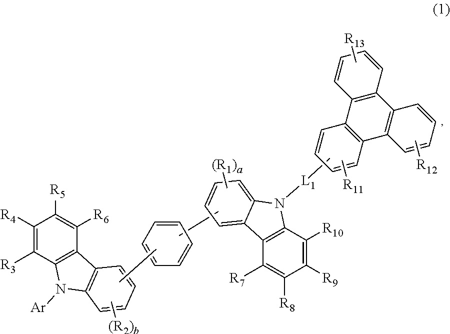
wherein:
Ar is an aryl group having 6 to 30 carbon atoms, a heteroaryl group having 5 to 30 carbon atoms, or an alkyl group having 1 to 15 carbon atoms,
R₁ to R₁₃ are each independently an aryl group having 6 to 30 carbon atoms, a heteroaryl group having 5 to 30 carbon atoms, an alkyl group having 1 to 15 carbon atoms, a halogen atom, a hydrogen, or a deuterium,
L₁ is a single bond or a divalent connecting group having 4 or more carbon atoms, and
a and b are each independently an integer of 0 to 3.

2. A material for an electroluminescence device, the material being represented by the following Formula 2: 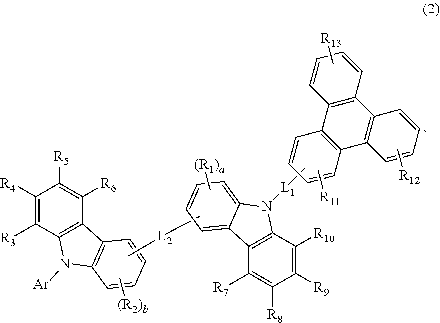
wherein:
Ar is an aryl group having 6 to 30 carbon atoms, a heteroaryl group having 5 to 30 carbon atoms, or an alkyl group having 1 to 15 carbon atoms,
R₁ to R₁₃ are each independently an aryl group having 6 to 30 carbon atoms, a heteroaryl group having 5 to 30 carbon atoms, an alkyl group having 1 to 15 carbon atoms, a halogen atom, a hydrogen, or a deuterium, L₁ and L₂ are each independently a single bond or a divalent connecting group having 4 or more carbon atoms, and
a and b are each independently an integer of 0 to 3.

3. A material for an electroluminescence device, the material being represented by the following Formula 3: 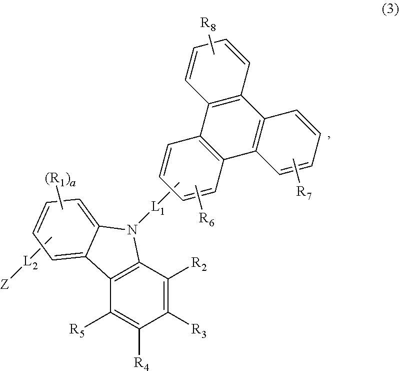
wherein:
R₁ to R₈ are each independently an aryl group having 6 to 30 carbon atoms, a heteroaryl group having 5 to 30 carbon atoms, an alkyl group having 1 to 15 carbon atoms, a halogen atom or a deuterium, L₁ is a single bond or a divalent connecting group having 4 or more carbon atoms,
L₂ is a divalent connecting group having 4 or more carbon atoms,
Z is an aryl group having 6 to 30 carbon atoms or a heteroaryl group having 5 to 30 carbon atoms, and
a is an integer of 0 to 3.

4. An electroluminescence device, comprising:
an emission layer; and
a positive electrode, wherein the material for an electroluminescence device as claimed, in claim 1 is in the emission layer or in another layer between the emission layer and the positive electrode.

5. An electroluminescence device, comprising:
an emission layer; and
a positive electrode, wherein the material for an electroluminescence device as claimed in claim 2 is in the emission layer or in another layer between the emission layer and the positive electrode.

6. An electroluminescence device, comprising:
an emission layer; and
a positive electrode, wherein the material for an electroluminescence device as claimed in claim 3 is in the emission layer or in another layer between the emission layer and the positive electrode.
